(19) United States
(12) Patent Application Publication
(10) Pub. No.: US 2002/0047500 A1
(43) Pub. Date: Apr. 25, 2002

(54) Composite ultrasonic therapeutic transducer and method manufacturing the same

(76) Inventors: Wen-Pin Lai, Hsinchu (TW); Jiann-Hwa Jeng, Hsinchu (TW)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 09/846,911

(22) Filed: May 1, 2001

(30) Foreign Application Priority Data
Jul. 24, 2000 (TW) 89/114,728

(51) Int. Cl. H01L 41/04

(52) U.S. Cl. 310/334

(57) ABSTRACT

This invention discloses a composite ultrasonic therapeutic transducer, which comprises a piezoelectric ceramic having a positive electrode and a negative electrode, and a metallic housing, and is characterized in that the piezoelectric ceramic is formed with at least one recess which is open to the negative electrode attached onto the metallic housing. Thus, the transducer has a higher impedance and a wider bandwidth, and is easy to reach a well impedance matching with a driver.

### BACKGROUND OF THE INVENTION

1. Field of the Invention

The present invention relates to a composite ultrasonic therapeutic transducer and a method of manufacturing the same, and in particular to a composite ultrasonic therapeutic transducer having a relatively higher impedance and a wider bandwidth as well as a method manufacturing the same.

2. Description of the Related Art

An ultrasonic therapeutic transducer is mainly used for medical health and beauty treatment. Depending upon applications, there are many types of design in regard to the ultrasonic therapeutic transducer. Such a classification generally is based upon the resonance frequency and acoustic output power of the ultrasonic therapeutic transducer. The current ultrasonic therapeutic transducer can be classified into two types: one is a type of being amplified by mechanic amplitude (i.e., Lagrange type) and the other is a type of a piezoelectric ceramic on a metal. The former operates at a lower frequency and outputs a stronger power and thus is usually used in the aspect of an ultrasonic medical operation or ultrasonic stone-breaker. The later operates at a higher frequency of about several MHz and thus has been used for beauty or for restoration or treatment for athletic injury to bone or muscle for a long time.

However, the transducer of the type of a piezoelectric ceramic on a metal should be accompanied by a driver, and thus has an issue of impedance matching between the driver and the transducer. In detail, if a large gap exists in the impedance matching, the energy of the driver will be reflected back or consumed. Consequently, the acoustic output power of the transducer is very small.

To overcome such a problem, a transformer was ever introduced between the transducer and the driver for the purpose of impedance matching. However, with the same size of the transducer, the impedance thereof will get down if its operating resonance frequency is raised up to 3 MHz for example. Thus, a well impedance matching is hard to come to true in such a manner. Alternatively, the coil number of the transformer has to increase. However, it will in turn complicate the manufacturing and mass-producing of the transformer. Therefore, as a solution to overcome the above drawback in impedance, increasing either the bandwidth of the transducer or the impedance thereof was considered.

A method of improving the bandwidth of the transducer was disclosed in U.S. Pat. No. 4,823,042, in which the shape of the metallic housing of the transducer is modified such that the bandwidths at a resonance point and at an anti-resonance point of the transducer are increased so as to increase the bandwidth and the acoustic output power of the transducer. However, it can only increase the bandwidth of the transducer but fails to overcome the drawback in impedance matching.

### BRIEF SUMMARY OF THE INVENTION

A main object of the present invention is to provide a composite ultrasonic therapeutic transducer having a wider bandwidth and a higher impedance which are adjustable, and a method of manufacturing the same.

To achieve the above object, this invention discloses a composite ultrasonic therapeutic transducer comprising a piezoelectric ceramic having a positive electrode and a negative electrode, and a metallic housing having an inner side surface attached onto the negative electrode of the piezoelectric ceramic. This invention is characterized in that the piezoelectric ceramic is formed with at least one recess which is open to the negative electrode so as to have a broken negative electrode and that the at least one recess is filled with glue.

As another aspect of this invention, this invention also discloses a method of manufacturing a composite ultrasonic therapeutic transducer constructed by a metallic housing having an inner surface and a bare piezoelectric ceramic having a positive electrode and a negative electrode. The method comprises the steps of:

forming at least one recess which is open to the negative electrode in the bare piezoelectric ceramic so as to form a piezoelectric ceramic having a broken negative electrode; filling the least one recess with glue; and attaching the broken negative electrode of the piezoelectric ceramic onto the inner surface of the metallic housing so as to fix the piezoelectric ceramic onto the metallic housing to form a composite ultrasonic therapeutic transducer.

By means of the above invention, the bandwidth and the impedance of the transducer increase and can be adjusted by changing the ratio of the broken negative electrode to an opening area of the recess. Thus, a well impedance matching between the transducer and the driver and a best acoustic output power are available without using a transformer or changing the coil number of the transformer.

### BRIEF DESCRIPTION OF THE DRAWINGS

In the following, preferred embodiments of the present invention will be described in detail in conjunction with the accompanying drawings, wherein:

FIG. 1 is a side view of an ultrasonic therapeutic transducer according to one embodiment of this invention;

FIG. 2 is a perspective view of a piezoelectric ceramic used in the transducer of FIG. 1;

FIG. 3 is a drawing showing the relationship of the electric impedance and the frequency in the transducer of FIG. 1;

FIG. 4 is a perspective view of a piezoelectric ceramic according to the other embodiment of this invention; and

FIG. 5 is a drawing showing the steps of manufacturing the transducer of FIG. 1.

### DETAILED DESCRIPTION OF THE INVENTION

In the following, a transducer according to this invention will be described in reference to drawings.

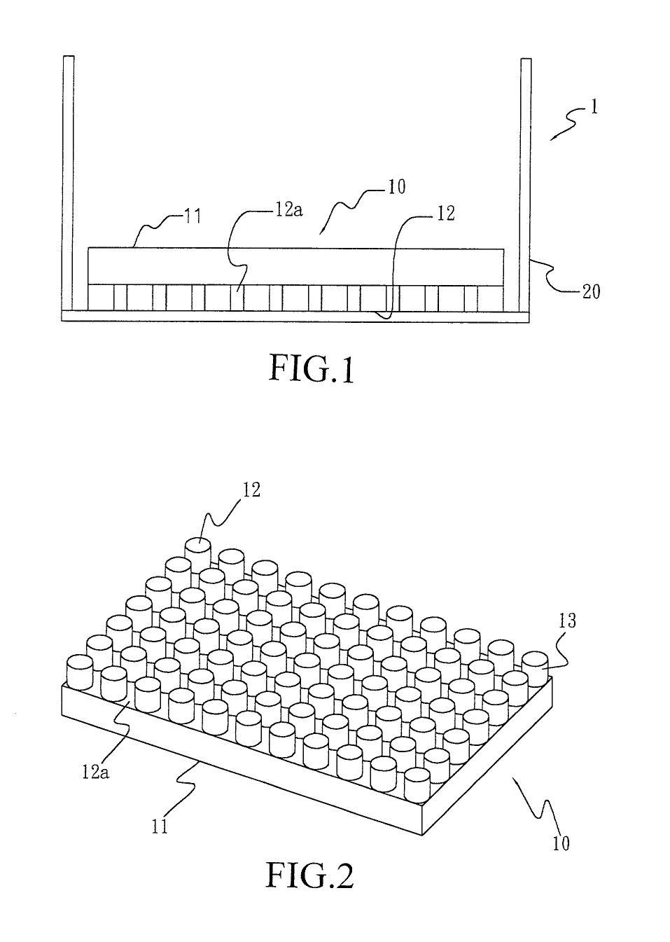

FIG. 1 shows a side view of a composite ultrasonic therapeutic transducer according to this invention. As shown in FIG. 1, the ultrasonic therapeutic transducer comprises a piezoelectric ceramic 10 and a metallic housing 20 for fixing the piezoelectric ceramic 10. The piezoelectric ceramic 10 is one of the series of piezoelectric transducer (PZT), and has a positive electrode 11 and a broken negative electrode 12. The metallic housing 20 has an inner side surface. The broken negative electrode 12 is attached to the inner side surface of the metallic housing 20. Moreover, the piezoelectric ceramic 10 is formed with a continuous recess 12a which has a particular depth and width. The recess 12a is filled with glue (not shown) such as epoxy.

FIG. 2 shows a perspective view of a piezoelectric ceramic 10 used in FIG. 1. As shown in FIG. 2, the recess 12a divides the piezoelectric ceramic into many parallel cylinder pillars 13 in a form of array. Each pillar 13 is interlinked at bottom to each other by the piezoelectric ceramic itself and has an outer end surface for forming the broken negative electrode 12.

According to the above structure, the ratio of the volume of the recess 12a, to be filled with glue, to that of the piezoelectric ceramic 10 will affect the bandwidth of the transducer 1. Thus, each of the end surfaces of the pillars should be spaced from the end surfaces of the other pillars by a distance smaller than half of the sound wavelength of the glue to be filled in the recess 12a, so as to avoid the filled glue from going into a mechanical resonance model, which will result in coupling of resonance model of the transducer 1.

Moreover, the depth of each recess 12a should also be appropriately selected. According to experimental data, it is found that a deeper recess can make the transducer 1 have a wider bandwidth, but result in a worse yield of the transducer 1. A shallow recess otherwise has no notable effect on the increase in the bandwidth of the transducer 1. Therefore, it is found that the depth of the recess 12a should not excess one third of the thickness of the piezoelectric ceramic 10 calculated from the negative electrode 12 to the positive electrode 11. As for the formation of the recess 12, an etching method can be applied.

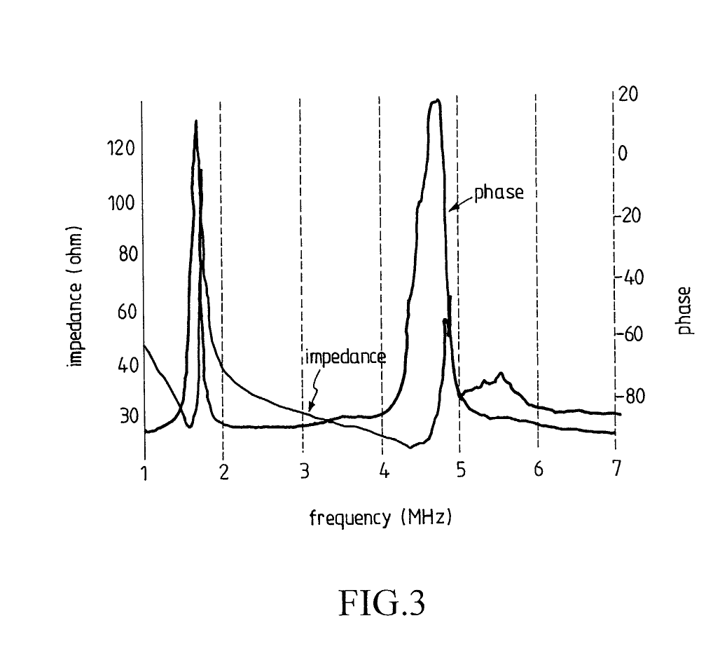

FIG. 3 shows the relationship of the electrical impedance of the transducer 1 with respect to the operating frequency thereof. As shown in FIG. 3, in a comparison to the prior art having a resonance impedance of 0.16 Ohm, the resonance impedance of the transducer 1 according to this invention is at least 20 times large than the prior art and reaches a scale of 4.72 Ohm. Moreover, the acoustic output power of the system using the transducer 1 is 5 times of that in the prior art. Furthermore, in this invention the distribution of the bandwidth with respect to a central frequency thereof is at a rate of 0.5%, which is large than a rate of 0.2% in the prior art.

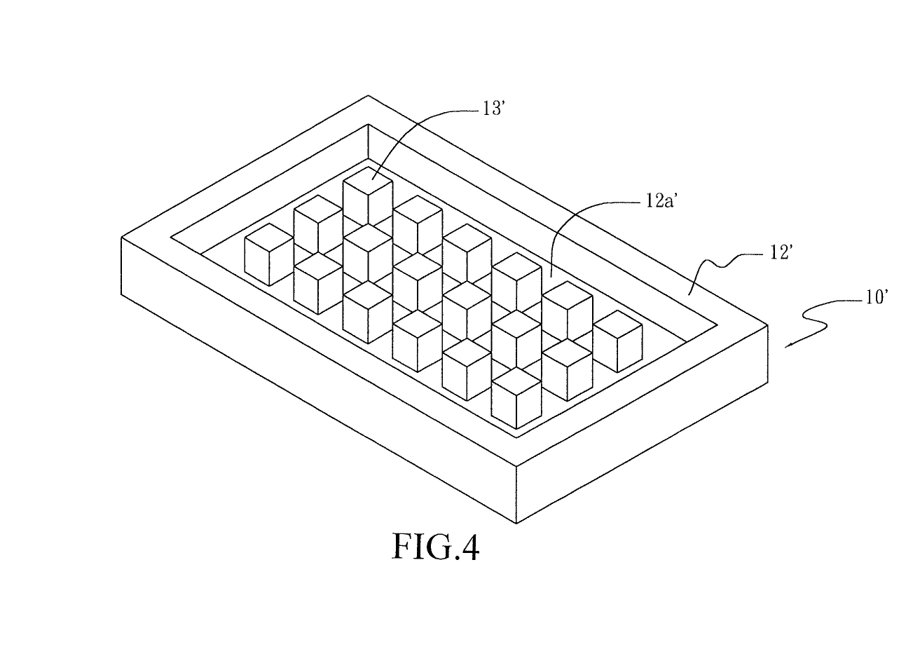

FIG. 4 shows a perspective view of a piezoelectric ceramic according to another embodiment of this invention. As shown in FIG. 4, a piezoelectric ceramic 10′ also has a broken negative electrode 12′ due to the provision of a recess 12a′ in the piezoelectric ceramic 10′. However, the recess 12a′ divides the piezoelectric ceramic 10′ into a lot of parallel rectangle pillars 13′. The outer end surfaces of these parallel rectangle pillars 13′ constitute the broken negative electrode 12′.

In this embodiment, the pitch of two parallel pillars 13′ and the depth of the recess 12a′ are determined in such a manner that the recess 12a is done. As for forming method, in addition to the above-mentioned etching method a method by means of cutting can also be used. Moreover, the recess 12a′ formed in the piezoelectric ceramic 10′ of this embodiment can also be called as a grid slot opening to the negative electrode 12′. A transducer using the piezoelectric ceramic of this embodiment can also obtain an effect of increasing bandwidth and impedance like the transducer in the former embodiment.

However, although the illustrated recess in each above embodiment is continuously formed in the piezoelectric ceramic, it can also be discrete to meet different demands. That is, in the above embodiment the recess is continuous and the negative electrode is discrete. However, in another design the broken negative electrode can be of a continuous grid shape formed by a lot of separated recess respectively opening to the negative electrode.

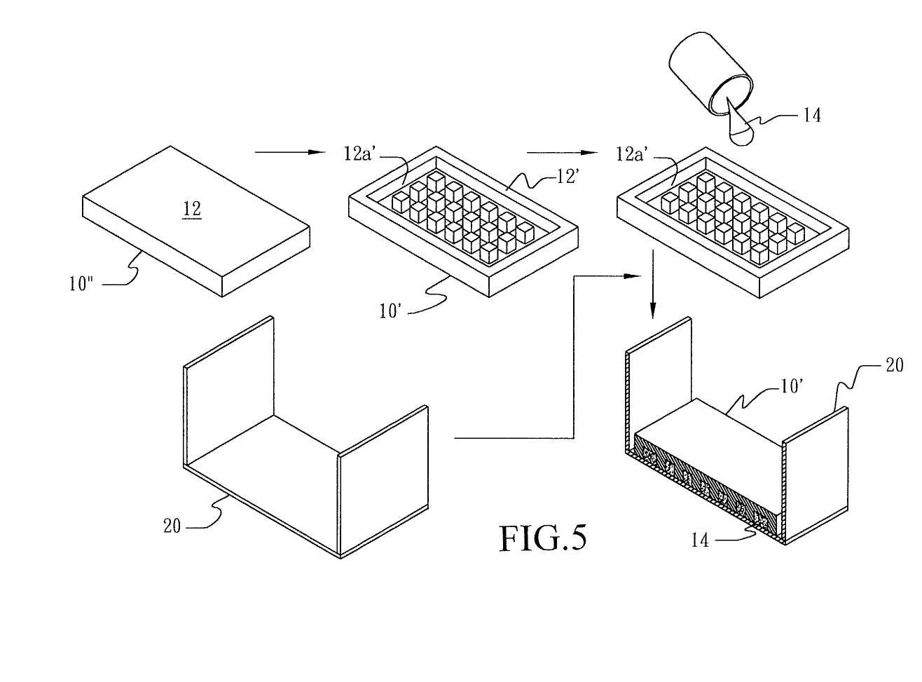

FIG. 5 shows the steps of manufacturing the above transducer. As shown in FIG. 5, before manufacturing the transducer a bare piezoelectric ceramic 10″ having a positive electrode and a negative electrode and a metallic housing 20 having an inner surface are provided. Next, a recess 12a′ which is open to the negative electrode is formed in the bare piezoelectric ceramic 10″ so as to form a piezoelectric ceramic 10′ having a broken negative electrode 12′. As mentioned above, such a formation of recess 12a′ can be carried out by etching method or cutting method.

Next, the recess 12a′ is filled with glue 14 such as epoxy. Lastly, the broken negative electrode 12′ of the piezoelectric ceramic 10′ is attached onto the inner surface of the metallic housing 20, by the allocation of the inner surface on the broken negative electrode 12′, and thus a composite transducer is completed.

In view of the above, by means of the structure and manufacturing method of this invention, a transducer having a wider bandwidth and a higher impedance is achieved. However, the above description is described by way of preferred embodiments, it is understood that the embodiments are used only to illustrate the technical concept of the present invention without limiting the scope thereof. It is therefore intended to show that all modifications and alterations that are readily apparent to those skilled in the art are within the scope as defined in the appended claims.

What is claimed is:

1. A composite ultrasonic therapeutic transducer comprising a piezoelectric ceramic having a positive electrode and a negative electrode, and a metallic housing having an inner side surface attached onto the negative electrode of the piezoelectric ceramic; characterized in that the piezoelectric ceramic is formed with at least one recess which is open to the negative electrode so as to have a broken negative electrode and that the at least one recess is filled with glue.

2. The transducer as claimed in claim 1, wherein the recess divides the piezoelectric ceramic into many pillars in a form of array, and each pillar has an end surface for constituting the broken negative electrode.

3. The transducer as claimed in claim 1, wherein the recess is formed by cutting.

4. The transducer as claimed in claim 1, wherein the recess is formed by etching.

5. The transducer as claimed in claim 1, wherein the glue is epoxy.

6. The transducer as claimed in claim 1, wherein the recess has a depth of one third of the thickness of the piezoelectric ceramic calculated from the negative electrode to the positive electrode.

7. The transducer as claimed in claim 2, wherein the end surfaces of the pillars are spaced from each other by a distance smaller than half of the sound wavelength of the glue.

8. A method of manufacturing a composite ultrasonic therapeutic transducer constructed by a metallic housing having an inner surface and a bare piezoelectric ceramic having a positive electrode and a negative electrode, comprising the steps of:
forming at least one recess which is open to the negative electrode in the bare piezoelectric ceramic so as to form a piezoelectric ceramic having a broken negative electrode;
filling the least one recess with glue; and
attaching the broken negative electrode of the piezoelectric ceramic onto the inner surface of the metallic housing so as to fix the piezoelectric ceramic onto the metallic housing to form a composite ultrasonic therapeutic transducer.
